(19) United States
(12) Patent Application Publication
(10) Pub. No.: US 2007/0284577 A1
(43) Pub. Date: Dec. 13, 2007

(54) Semiconductor device including fuses and method of cutting the fuses

(76) Inventors: Kyoung-suk Lyu, Yongin-si (KR); Kwang-kyu Bang, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/723,277

(22) Filed: Mar. 19, 2007

(30) Foreign Application Priority Data
Jun. 12, 2006 (KR) 10-2006-0052592

(51) Int. Cl. H01L 29/10; H01L 21/67

(52) U.S. Cl. 257/48; 438/4; 257/E29.043

(57) ABSTRACT

A semiconductor device may include multiple fuses spaced at a same pitch from each other and a check pattern spaced a predetermined distance from one side of the fuses, where the check pattern has the same width, height, and pitch as the fuses, and the fuses may be formed of a conductive material that may be one of W, WSi, Al or Cu.

### BACKGROUND OF THE INVENTION

1. Field of the Invention

The present invention relates to a semiconductor device and a method for manufacturing the same. More particularly, the present invention relates to a semiconductor device including fuses and a method of cutting the fuses.

2. Description of the Related Art

It is practically impossible for every memory cell of a semiconductor device to be in good working condition because defective cells inevitably occur during manufacture of the semiconductor device. To solve this problem, a redundancy cell around a defective cell may be used. That is, a fuse connected to the defective memory cell may be connected so that the redundancy cell is used to replace the defective memory cell. Therefore, although a defective memory cell may be present in an integrated circuit, the integrated circuit may operate normally via the redundancy cell. This is called a repair process.

A related art repair method applied to the semiconductor device may entail cutting and removing the polysilicon or metal fuse of a defective cell. The fuse may be generally cut by a laser beam having a constant diameter. FIG. 1 illustrates a plan view of a related art process of cutting a fuse using a laser beam. Fuses 12a to be cut and fuses 12b not to be cut may be formed on a layer 10, e.g., an insulating layer (the fuses 12a to be cut are marked by x). Portions of the fuses 12a marked by x may be cut with a laser beam.

FIG. 2 illustrates an enlarged view of FIG. 1 to delineate a process margin d1 for a process of cutting a fuse. Referring to FIG. 2, the process margin d1 may be calculated to be about half the value obtained by subtracting the width d5 of the fuse 12b, the diameter d3 of a laser beam (L), and a component installation error d2 from d4 (2×pitch). That is, d1=(d4−d5−d3−d2)/2. If the process margin d1 is too small, adjacent fuses may be damaged by the laser beam (L). Therefore, it may be important cut the fuse so as to accurately control the process margin d1.

The process margin d1 may be different from an expected value due to errors and deviations. For example, a position deviation of the laser beam (L) may occur when the center of the laser beam (L) is not aligned with the center of the fuse 120a, a scanning angle error may occur when the laser beam (L) is not irradiated onto the fuse 12a at a right angle, a focusing error of the laser beam (L) may occur due to a change in the diameter d3 of the laser beam (L), and/or component installation error d2 may occur, etc.

If the fuses 12a are cut when the process margin d1 is insufficient, as illustrated in FIG. 3, adjacent fuses may be damaged (refer to oval boxes in FIG. 3). Further, after an inspection (also called a BIN test) to determine whether fuses are properly repaired, hundreds to thousands of fuses are simultaneously inspected for damage. It thus may be difficult to accurately find out the cause of the damaged fuses.

Also, reducing the design rule of semiconductor devices may make it more difficult to keep the process margin d1 in accordance with the design rule. The spot position and the diameter of the laser beam (L) should thus be precisely modulated to keep the process margin d1 at a desired level.

### SUMMARY OF THE INVENTION

The present invention is therefore directed to a semiconductor device including fuses, which substantially overcomes one or more of the problems due to the limitations and disadvantages of the related art.

It is therefore a feature of an embodiment of the present invention to provide a method of checking the process margin of a laser beam for cutting the fuses and the process margin of the fuses.

At least one of the above and other features and advantages of the present invention may be realized by providing a semiconductor device that may include multiple fuses spaced at a same pitch from each other, and a check pattern spaced a predetermined distance from one side of the fuses, wherein the check pattern has a same width, height, and pitch as the fuses.

The fuses may be formed of a conductive material, and the conductive material may be at least one of W, WSi, Al or Cu. The check pattern may be installed on one chip. The check pattern may be spaced apart from the one side of the fuses by the pitch. The check pattern may have a shape enclosing the laser beam to be irradiated onto the fuse. The check pattern may be a plane tetragon or a plane square plane. The check pattern may include a plurality of neighboring tetragons. Alternatively, the check pattern may include multiple neighboring tetragons having sides of different lengths.

At least one of the above and other features of the present invention may be obtained by providing a method of cutting fuses of a semiconductor device that includes irradiating a laser beam onto a check pattern, the check pattern being spaced a predetermined distance from one side of the fuses and having the same width and height as those of the fuses, and determining whether the check pattern is damaged.

The method may further include, prior to the irradiating of the laser beam, aligning a wafer having the fuses and determining the ideal energy of the laser beam for cutting the fuses. The determining may include checking whether at least one side of the check pattern is damaged. The determining may be performed using a check pattern having sides of different lengths for laser beams having different diameters. The check pattern may function to check a margin between the laser beam and fuses adjacent to the fuse to be cut. The check pattern may check at least one of a position error, a slope error, a focusing error, a component installation error, or energy of the laser beam. The check pattern may check the laser beam in a direction perpendicular to the fuses. The check pattern may simultaneously check the laser beam in a first direction perpendicular to the fuses and in a second direction perpendicular to the first direction. The energy level of the laser beam may be determined at a range of about 0.01 to 0.2 μj at intervals of about 0.01 μj.

The above information disclosed in this Background section is only for enhancement of understanding of the background of the invention and therefore it may contain information that does not form the prior art that is already known in this country to a person of ordinary skill in the art.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a plan view of stages of a process of cutting a fuse using a laser beam;

FIG. 2 illustrates a partial enlarged view of FIG. 1 depicting a process margin of the process of cutting a fuse;

FIG. 3 is a photomicrograph showing damage of an adjacent fuse;

FIG. 4A illustrates a plan view of stages of a process of checking a process margin of a laser beam according to an embodiment of the present invention;

FIG. 4B illustrates a sectional view taken along line 4B-4B′ of FIG. 4A;

FIGS. 5A through 5E illustrate stages of a method of checking a process margin using check patterns according to embodiments of the present invention; and

FIGS. 6A through 6D illustrate plan views of combinations of check patterns according to other embodiments of the present invention.

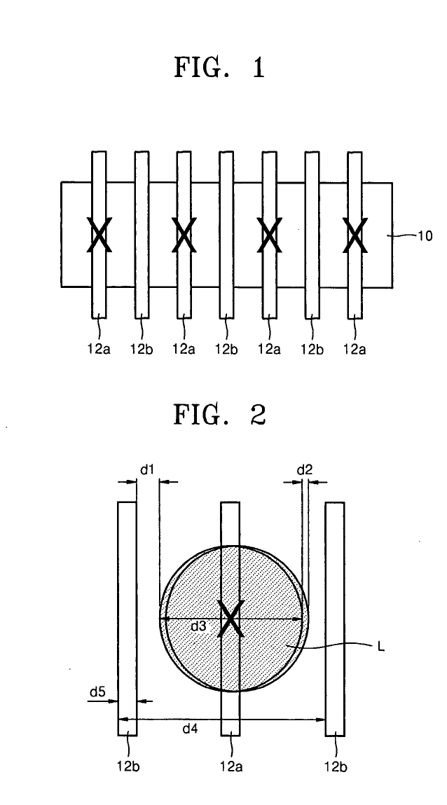

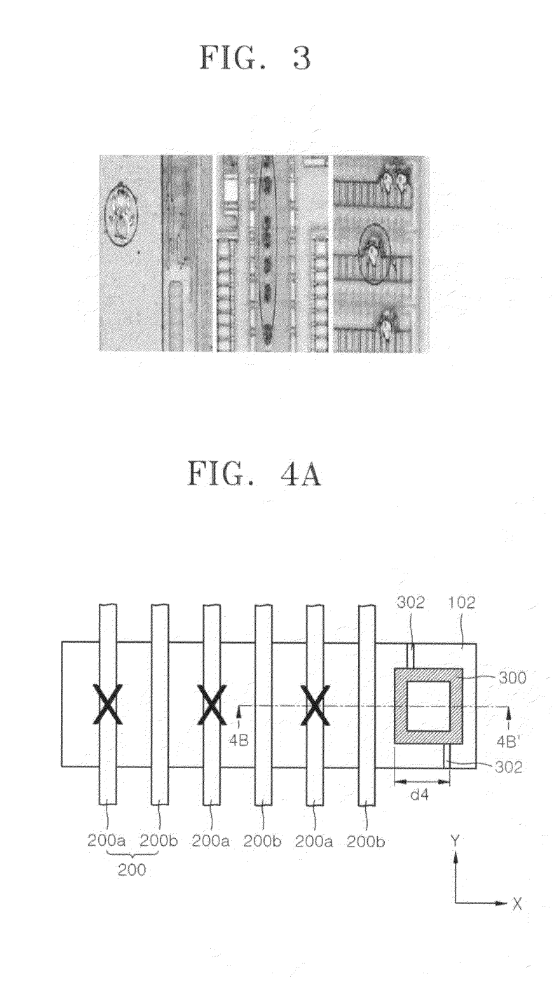

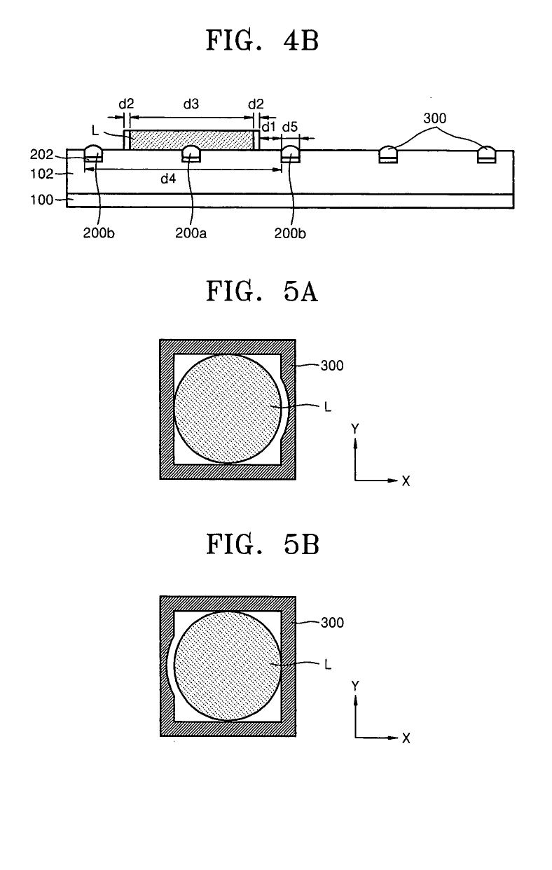

### DETAILED DESCRIPTION OF THE INVENTION

Korean Patent Application No. 10-2006-0052592, filed on Jun. 12, 2006, in the Korean Intellectual Property Office, and entitled: “Semiconductor Device Including Fuses and Method of Cutting the Fuses,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

According to embodiments of the present invention, a laser beam may be used to cut fuses, and a check pattern may be used to maintain a constant process margin between the fuses. At least one check pattern may be installed on a chip of a semiconductor device. In detail, one or more check patterns may be installed on one side of fuses of a unit chip or on one side of fuses connected to redundancy cells. If necessary, the check pattern may be installed on various positions of a unit chip of a semiconductor.

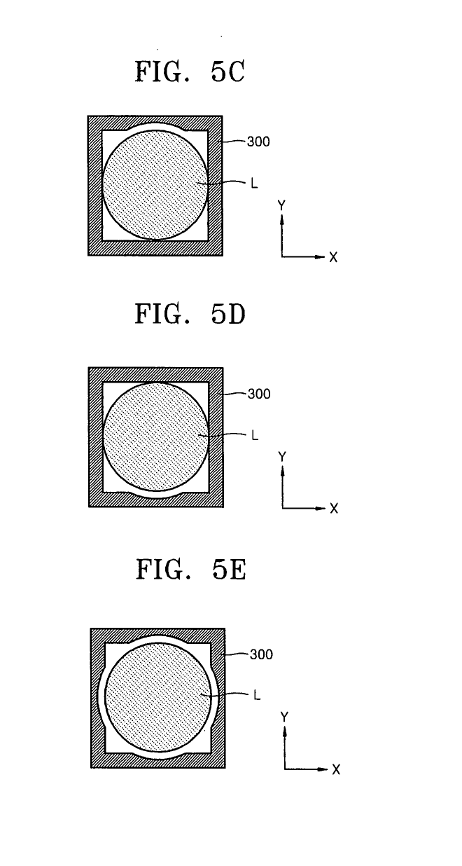

FIG. 4A illustrates a plan view of stages of checking a process margin of a laser beam according to an embodiment of the present invention. FIG. 4B illustrates a sectional view taken along line 4B-4B′ in FIG. 4A.

Referring to FIG. 4A and FIG. 4B, when fuses 200a to be cut and fuses 200b not to be cut are formed on a layer, e.g., insulating layer 102 deposited on a substrate 100 (e.g. a semiconductor), the fuses 200a to be cut may be marked by x. The fuses 200a marked by x may be cut by a laser beam (L). The fuses 200 may be spaced apart from each other by the same pitch. The fuses 200 may be made of conductive materials, e.g., alloys including W, WSi, Al, Cu, etc. A layer 202 may be deposited to improve the adhesive property of the fuses 200

A process margin d1 may be calculated as being about half the value obtained by subtracting the width d5 of the fuse 200b, the diameter d3 of the laser beam (L), and a component installation error d2 from d4 (2×pitch). That is, d1=(d4−d5−d3−d2)/2. The process margin d1 may be defined as a width of a region located at one side of the fuse 200b. The process margin d1 may be measured using a check pattern 300 having the same width and height as the width d5 and height of the fuses 200. The pitch between the fuses 200 and the check pattern 300 may have same pitch as that of the fuses 200. The check pattern 300 may be used to determine the process margin d1 related to the laser beam (L). The check pattern 300 may have the same pitch as that of the fuses 200.

The check pattern 300 may be used to check the process margin d1 in a first direction, e.g., an x-axis direction, perpendicular to the fuses 200 and in a second direction, e.g., a y-axis direction, perpendicular to the first direction, respectively. Further, the check pattern 300 may be simultaneously used to check the process margin d1 in the first and second directions. As illustrated in FIGS. 4A and 4B, although the check pattern 300 may have a tetragon shape with a predetermined width, the check pattern 300 may have other shapes as long as the check pattern 300 encloses the laser beam (L). The check pattern 300 may, e.g., have a square shape with a predetermined width. Damage to the check pattern 300 may be determined by applying a current or voltage to the check pattern 300 through conductive lines 302, which are electrically connected to the check pattern 300, and measuring a change in the resistance of the check pattern 300. Also, damage to the check pattern 300 may be visually determined by the naked eye using a display device.

The check pattern 300 may be formed by the following process. A conductive metal layer may be deposited on the insulating layer 102 and the fuses 200 so that the check pattern 300 may be simultaneously formed by a general lithography process. After that, an oxide layer and a nitride layer may be further deposited as a passivation layer. Portions of the oxide layer and the nitride layer located above the fuses 200 and the check pattern 300 may be cut to form a window. The check pattern 300 of the present invention may thus be readily formed during the process of forming the fuses 200.

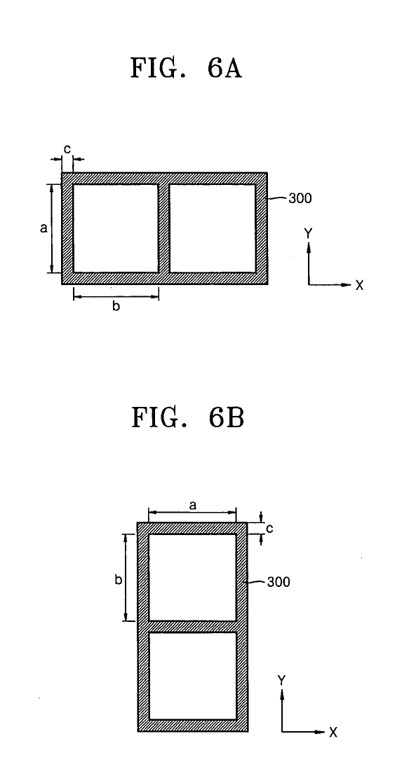

FIGS. 5A through 5E illustrate stages in a method of checking the process margin d1 using the check pattern 300 according to an embodiment of the present invention. A check pattern 300 having a square shape may be used to describe the method.

Referring to FIGS. 5A through 5E, the check pattern 300 may be used to check the process margin d1 of the laser beam (L) in a first direction (e.g. the x-axis direction) perpendicular to the fuses 200. That is, a right side of the check pattern 300 may be damaged in the x-axis direction as illustrated in FIG. 5A, or a left side of the check pattern 300 may be damaged in the x-axis direction as illustrated in FIG. 5B. Damage of the check pattern 300 means that the process margin d1 may be narrow. The damage may be caused by errors and deviations. For example, a position deviation of the laser beam (L) may occur when the center of the laser beam (L) is not aligned with the center of the fuse 200a, a scanning angle error may occur when the laser beam (L) is not irradiated onto a fuse at a right angle, a focusing error of the laser beam (L) may occur due to a change in the diameter d3 of the laser beam (L), and/or a component installation error may occur, etc.

The check pattern 300 may be used to check the process margin d1 in the second direction (the y-axis direction) perpendicular to the first direction. That is, the upper portion of the check pattern 300 may be damaged in the y-axis direction as illustrated in FIG. 5C, or the low portion of the check pattern 300 may be damaged in the y-axis direction as illustrated in FIG. 5D. Also, referring to FIG. 5E, the process margin d1 of the laser beam (L) in the second direction perpendicular to the first direction may be checked simultaneously.

Generally, in the process of cutting fuses, an energy level of the laser beam (L) may be determined after aligning a wafer bearing fuses. For example, the energy level of the laser beam (L) may be determined in a range of, e.g., about 0.05 to 0.2 μj (where μj is microjoules), by scanning a predetermined energy range from a low energy level to a high energy level, e.g., about 0.01 to 0.3 μj, at intervals of about 0.01 μj. In other words, while varying the energy level of the laser beam (L) at intervals of 0.01 μj within the predetermined energy range, the check pattern 300 may be scanned with the laser beam (L) to determine whether the check pattern 300 is damaged by the laser beam (L). In this way, the energy level of the laser beam (L) may be easily determined.

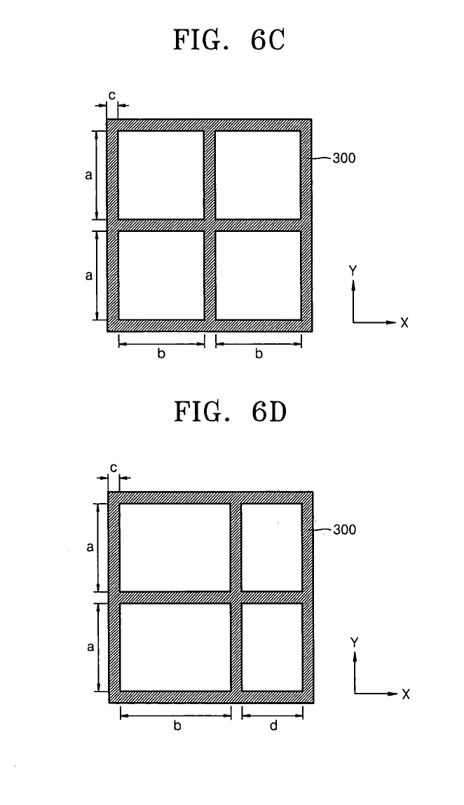

Combinations of multiple tetragonal check patterns may be used in the present invention. FIGS. 6A through 6D illustrate plan views of combinations of check patterns according to embodiments of the present invention.

Referring to FIG. 6A through 6D, each of the check patterns may have a tetragon shape with a height (a) and a length (b). The check pattern may have a uniform width (c). The height (a) and the length (b) of the check pattern may be the same. FIG. 6A illustrates two check patterns combined in an x-axis direction, and FIG. 6B illustrates two check patterns combined in a y-axis direction. The check patterns 300 may have a uniform width (c). When a combination of two check patterns is used, the process margin d1 of the laser beam (L) may be measured twice along a coupled direction of the check patterns 300. Further, when two check patterns 300 are arranged both in the x-axis and y-axis directions, the process margin d1 may be measured twice along the x-axis direction and twice in the y-axis direction.

The check patterns 300 may include multiple adjacent tetragons having sides of different lengths. For example, referring to FIG. 6D, check patterns 300 may be formed to match laser beams (L) having different diameters. That is, the check patterns 300 may have the same height (a) and different lengths (b) and (d). The check patterns having the different lengths (b) and (d) may be used in different fuse cutting processes. For example, the check pattern 300 having the height (a) and the length (b) may be used for a fuse pattern having a pitch of 2.0 μm, and the check pattern 300 having the height (a) and the length (d) may be used for a fuse pattern having a pitch of 1.5 μm.

According to the fuse-containing semiconductor device and method of cutting the fuses of the present invention, a check pattern spaced a predetermined distance from one side of the fuses and having the same width, height, and pitch as the fuses may be formed, so as to be usable to check the process margin of the laser beam in the fuse cutting process. Also, the check pattern may be easily formed in the process of forming the fuses. Further, in the fuse cutting process, the energy level of the laser beam may be easily determined by evaluating whether the check pattern is damaged by the laser beam.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor device, comprising:
a plurality of fuses spaced at a same pitch from each other; and
a check pattern spaced a predetermined distance from one side of the fuses, wherein the check pattern has a same width, height, and pitch as the fuses.

2. The device as claimed in claim 1, wherein the fuses are formed of a conductive material.

3. The device as claimed in claim 2, wherein the conductive material comprises at least one of W, WSi, Al or Cu.

4. The device as claimed in claim 1, wherein at least one check pattern is installed on one chip.

5. The device as claimed in claim 1, wherein the check pattern is spaced apart from the one side of the fuses by the pitch.

6. The device as claimed in claim 1, wherein the check pattern has a shape enclosing a laser beam to be irradiated onto the fuse.

7. The device as claimed in claim 1, wherein the check pattern is plane tetragon.

8. The device as claimed in claim 1, wherein the check pattern is plane square plane.

9. The device as claimed in claim 1, wherein the check pattern comprises a plurality of neighboring tetragons.

10. The device as claimed in claim 1, wherein the check pattern comprises a plurality of neighboring tetragons having sides of different lengths.

11. The device as claimed in claim 1, wherein the pitch is about 1.5 μm to about 2 μm.

12. A method of cutting fuses of a semiconductor device, comprising:
irradiating a laser beam onto a check pattern, the check pattern being spaced a predetermined distance from one side of the fuses and having a same width and height as the fuses; and
determining whether the check pattern is damaged.

13. The method as claimed in claim 12, further comprising:
prior to the irradiating of the laser beam, aligning a wafer having the fuses and determining an energy level of the laser beam to cut the fuses.

14. The method as claimed in claim 12, wherein the determining includes checking whether at least one side of the check pattern is damaged.

15. The method as claimed in claim 12, wherein the determining is performed using a check pattern having sides of different lengths for laser beams having different diameters.

16. The method as claimed in claim 12, wherein the check pattern functions to check a margin between the laser beam and fuses adjacent to the fuse to be cut.

17. The method as claimed in claim 12, wherein the check pattern functions to check at least one of a position error, a slope error, a focusing error, a component installation error, or energy of the laser beam.

18. The method as claimed in claim 12, wherein the check pattern functions to check the laser beam in a direction perpendicular to the fuses.

19. The method as claimed in claim 12, wherein the check pattern functions to simultaneously check the laser beam in a first direction perpendicular to the fuses and in a second direction perpendicular to the first direction.

20. The method according to claim 12, wherein an energy level of the laser beam is determined at a range of about 0.01 to 0.2 μj at intervals of about 0.01 μj.
